(19) United States
(12) Patent Application Publication
(10) Pub. No.: US 2005/0274978 A1
(43) Pub. Date: Dec. 15, 2005

(54) Single metal gate material CMOS using strained si-silicon germanium heterojunction layered substrate

(76) Inventors: Dimitri A. Antoniadis, Newton, MA (US); Judy L. Hoyt, Newton, MA (US); Jongwan Jung, Somerville, MA (US); Shaofeng Yu, Plano, TX (US)

Correspondence Address: Matthew E. Connors;Gauthier & Connors LLP, Suite 2300, 225 Franklin Street, Boston, MA, 02110, US

(21) Appl. No.: 11/138,951

(22) Filed: May 26, 2005

Related U.S. Application Data
(60) Provisional application No. 60/575,039, filed on May 27, 2004.

(51) Int. Cl. H01L 31/0328

(52) U.S. Cl. 257/192

(57) ABSTRACT

Strained Si/strained SiGe dual-channel layer substrate provides mobility advantage and when used as a CMOS substrate enables single workfunction metal-gate electrode technology. A single metal electrode with workfunction of 4.5 eV produces near ideal CMOS performance on a dual-channel layer substrate that consists sequentially of a silicon wafer, an epitaxially grown 30% Ge relaxed SiGe layer, a compressively strained 60% Ge layer, and a tensile-strained Si cap layer.

### PRIORITY INFORMATION

This application claims priority to U.S. Provisional Patent Application Ser. No. 60/575,039, filed May 27, 2004, which is incorporated herein by reference in its entirety.

### BACKGROUND OF THE INVENTION

1. Field of Invention

The present invention relates generally to the field of semiconductor substrates. More specifically, the present invention is related to the use of a single metal-gate material CMOS using strained Si/SiGe heterojunction layered substrate.

2. Discussion of Prior Art

The references described below provide a general teaching in the area of substrate structures with enhanced electron and hole mobilities and in the area of integrating metal-gates, but none of the references teach or suggest the use of a single metal-gate material CMOS enabled by the use of a strained Si/SiGe heterojunction layered substrate. In addition, none of the references achieve enhanced electron and hole mobilities simultaneous with the use of a single metal-gate material.

The paper to Jung et al. entitled, “Implementation of Both High-Hole and Electron Mobility in Strained Si/Strained Si_{1-y}Ge_{y} on Relaxed Si₁₋ₓGeₓ (x<y) Virtual Substrate”, teaches a dual heterostructure substrate that enhances hole and electron mobility. Jung et al. however, fail to teach or suggest the use of a single metal-gate material CMOS using a strained Si/SiGe heterojunction layered substrate.

The papers to Tavel et al. (entitled “Totally Sliced (CoSi₂) Polysilicon: a Novel Approach to Very Low-Resistive Gate (˜2/sq.) Without Metal CMP Nor Etching”), Kedzierski et al. (entitled “Metal-Gate FinFET and Fully-Depleted SOI Devices Using Total Gate Silicidation”), and Polishchuk et al. (entitled “Dual Work Function Metal Gate CMOS transistors by Ni—Ti Interdiffusion”) generally teach the integration of metal-gates, but they fail to teach or suggest the use of a single metal-gate material CMOS using a strained Si/SiGe heterojunction layered substrate, and achievement of the appropriate workfunctions for the n- and p-channel devices remains problematic.

Whatever the precise merits, features, and advantages of the above cited references, none of them achieves or fulfills the purposes of the present invention.

### SUMMARY OF THE INVENTION

The present invention provides for a semiconductor structure comprising at least a layer of compressively strained SiGe, a layer of tensile strained Si, and an optimized gate stack. The optimized gate stack comprises a gate insulator and a gate electrode, wherein the optimized gate stack is formed using a single metal material. The strain in the strained Si and strain and/or Ge content in strained SiGe are adjusted to enable use of said single metal material acting as said optimized gate electrode for both n- and p-MOSFETs.

The present invention provides for a semiconductor structure comprising a CMOS substrate used in conjunction with a single metal material used as an optimized gate electrode. The CMOS substrate structure further comprises a silicon substrate, a relaxed Si₁₋ₓGeₓ layer disposed on top of the substrate, a layer of compressively strained Si_{1-y}Ge_{y} disposed on top of the relaxed Si₁₋ₓGeₓ layer, with Ge composition y being greater than x, and a layer of tensile strained silicon disposed on top of the compressively strained Si_{1-y}Ge_{y} layer. The single metal material (e.g., TiN) used as an optimized gate electrode in conjunction with the CMOS substrate structure acts as the gate electrode for both n- and p-MOSFETs.

In an extended embodiment, the semiconductor structure comprises a graded buffer layer of Si₁₋ᵣGeᵣ disposed between said silicon substrate and said relaxed Si₁₋ₓGeₓ layer, wherein 0≦r≦x.

The strained-Si—SiGe dual channel layer substrate maximizes electron and hole transport characteristics, wherein varying thickness of said layer of tensile strained silicon provides for n-MOSFET or p-MOSFET substrates. For example, tensile strained silicon thickness in the range of 3-10 nm is used for n-MOSFETs and tensile strained silicon thickness in the range of 1-3 nm is used for p-MOSFETs.

The Ge fractions x and y chosen to enable single metal-gate workfunction with suitable threshold voltage for both n-MOSFETs and p-MOSFETs. The Strained Si and SiGe shifts energy levels allowing workfunctions of n-MOSFET and p-MOSFET to overlap such that a single metal material gate can be chosen with a workfunction in the overlapping region.

The present invention also provides for a method for forming a strained-Si—SiGe dual channel layer substrate structure and an optimized single metal-gate electrode comprising the steps of: (a) growing a layer of compressively strained SiGe; (b) growing a layer of tensile strained Si disposed on top of said compressively strained SiGe layer, and (c) forming an optimized gate stack comprising a gate insulator and a gate electrode using a single metal material, wherein strain in said strained Si and strain and/or Ge content in strained SiGe are adjusted to enable use of said single metal material acting as said optimized gate electrode for both n- and p-MOSFETs.

The present invention also provides for a method for forming a strained-Si—SiGe dual channel layer substrate structure and an optimized single metal-gate electrode, wherein the method comprises the steps of: (a) gradually increasing Ge content to a predetermined value x on a silicon substrate and growing a relaxed Si₁₋ₓGeₓ layer; (b) pseudomorphically growing a layer of compressively strained Si_{1-y}Ge_{y} on top of the relaxed Si₁₋ₓGeₓ layer, wherein Ge composition y is greater than x; (c) pseudomorphically growing a layer of tensile strained silicon on top of the compressively strained Si_{1-y}Ge_{y} layer, and (d) forming an optimized gate stack consisting of a gate insulator and a gate electrode using a single metal material, wherein the single metal material acts as the gate electrode for both n- and p-MOSFETs.

Hence, the present invention allows utilization of a single metal material as the optimized metal-gate electrode for both n- and p-MOSFETs. The Ge content and thickness of the materials in the heterojunction substrate are adjusted to obtain the correct threshold voltage for both n- and p-MOSFETs, for a single metal-gate electrode material that is used for both the n- and p-MOSFETs. The use of metal-gate electrodes increases device operating speed. In addition to enabling the use of a single metal-gate electrode with proper threshold voltage, the present invention's structure also improves the transport properties of the carriers and thus further improves device operating speed.

### BRIEF DESCRIPTION OF THE DRAWINGS

FIG. 1 illustrates a substrate structure as per the present invention.

FIGS. 2(a) and 2(b) show an example of n-MOSFET and p-MOSFET substrate structures according to the present invention.

FIG. 3 shows the band structure of the substrate in this invention for the instance of y=0.6 and x=0.3.

FIG. 4 shows device simulation results for one embodiment of this invention (substrate with y=0.6 and x=0.3).

FIG. 5 illustrates measured mobility enhancement factors for electrons and holes in dual-channel structures with 10- and 3-nm-thick Si cap, respectively, and TiN gate electrodes.

FIG. 6 illustrates measured and simulated threshold voltages of long channel n-MOS (9.5-nm-thick Si cap layer) and p-MOS (3-nm-thick Si cap layer) transistors with TiN gate electrode.

### DESCRIPTION OF THE PREFERRED EMBODIMENTS

While this invention is illustrated and described in a preferred embodiment, the invention may be produced in many different configurations. There is depicted in the drawings, and will herein be described in detail, a preferred embodiment of the invention, with the understanding that the present disclosure is to be considered as an exemplification of the principles of the invention and the associated functional specifications for its construction and is not intended to limit the invention to the embodiment illustrated. Those skilled in the art will envision many other possible variations within the scope of the present invention.

Metal-gate electrode has been regarded as one of the main technology enablers for continued scaling of Si based CMOS down to nanometer scale. Due to the nature of band energy structure of conventional Si substrate, the metal workfunction that is required to optimize n-channel MOSFET performance differs from that of p-channel MOSFET by a wide range. Ideal Si n-MOSFET metal electrode workfunction is between 4.0 eV and 4.2 eV while that for p-MOSFET is between 5.0 eV to 5.2 eV. Therefore, metal-gate technology for normal Si substrate would need two different types of metal-gate materials and would involve a much more complex integration process. This has been one of the major obstacles that prevent the metal-gate technology from being widely adopted and used today.

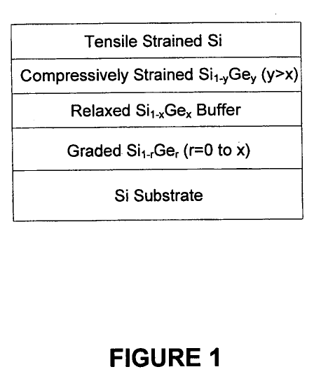

This invention proposes a unique semiconductor substrate structure as shown in FIG. 1, consisting of tensile strained silicon, compressively strained Si_{1-y}Ge_{y} with high Ge composition, relaxed Si₁₋ₓGeₓ (x<y), and silicon substrate, that provides optimal n-MOSFET and p-MOSFET performance with a single metal material as gate electrode. For n-channel and p-channel devices, the layer structure of the substrate is the same, but the top strained silicon layer thickness needs to be different. n-MOSFET substrate would need thicker cap silicon layer to ensure that the electron channel resides entirely in the strained Si layer. It usually requires silicon cap thickness greater than 3 nm but less than the critical thickness to maintain strain. For p-MOSFET, the cap Si layer thickness needs to be limited to be less than 3 nm. The thin cap Si layer is needed to ensure that the carriers in compressively strained SiGe layer dominate the channel conduction, i.e., control the threshold voltage and transport properties, and to minimize the subthreshold slope degradation caused by the top Si layer. In an extreme case, the Si cap layer thickness could be zero.

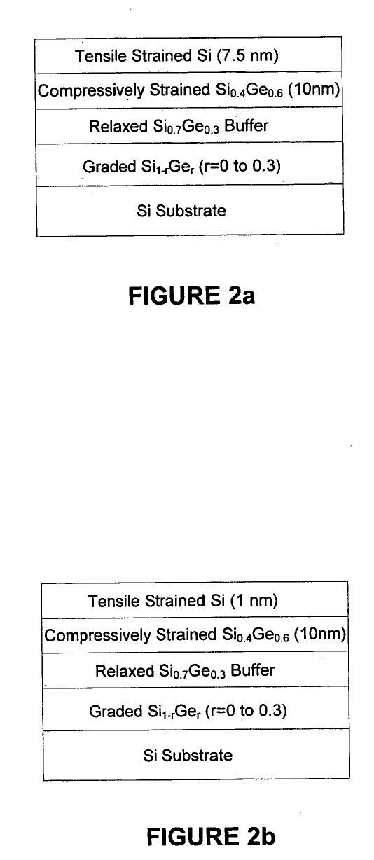

FIGS. 2(a) and 2(b) show an example of the corresponding substrate structures for n-MOSFET and p-MOSFET, respectively, with detailed Ge compositions and layer thicknesses. FIG. 2(a) illustrates an n-MOSFET with a Si cap layer thickness of 4 nm. Tensile strained silicon thickness in the range of 3-10 nm is used for n-MOSFETs. FIG. 2(b) illustrates a p-MOSFET with a Si cap layer thickness of 1 nm. Tensile strained silicon thickness in the range of 1-3 nm is used for p-MOSFETs.

In one embodiment, the present invention provides for a semiconductor structure comprising at least a layer of compressively strained SiGe, a layer of tensile strained Si, and an optimized gate stack, wherein the optimized gate stack comprises a gate insulator and a gate electrode and the optimized gate stack is formed using a single metal material. The strain in the strained Si and strain and/or Ge content in strained SiGe are adjusted to enable use of said single metal material acting as said optimized gate electrode for both n- and p-MOSFETs.

In another embodiment, the present invention provides for a semiconductor structure comprising a CMOS substrate (as described above) used in conjunction with a single metal material used as an optimized gate electrode. In this embodiment, the CMOS substrate structure comprises a silicon substrate, a relaxed Si₁₋ₓGeₓ layer disposed on top of the substrate, a layer of compressively strained Si_{1-y}Ge_{y} disposed on top of the relaxed Si₁₋ₓGeₓ layer, with Ge composition y being greater than x, and a layer of tensile strained silicon disposed on top of the compressively strained Si_{1-y}Ge_{y} layer. The single metal material (e.g., TiN) used as an optimized gate electrode in conjunction with the CMOS substrate structure acts as the gate electrode for both n- and p-MOSFETs.

In yet another embodiment, the present invention provides for a semiconductor structure comprising a strained-Si—SiGe dual channel layer substrate and a single metal material used as an optimized gate electrode. The strained-Si—SiGe dual channel layer structure further comprises: a silicon substrate; a graded buffer layer of Si₁₋ᵣGeᵣ disposed on top of said substrate, wherein 0≦r≦x; a relaxed Si₁₋ₓGeₓ layer disposed on top of said substrate graded buffer layer of Si₁₋ᵣGeᵣ; a layer of compressively strained Si_{1-y}Ge_{y} disposed on top of said relaxed Si₁₋ₓGeₓ layer, with Ge composition y being greater than x; and a layer of tensile strained silicon disposed on top of said compressively strained Si_{1-y}Ge_{y} layer, said strained-Si—SiGe dual channel layer substrate maximizing electron and hole transport characteristics, wherein varying thickness of said layer of tensile strained silicon provides for n-MOSFET or p-MOSFET substrates.

For example, tensile strained silicon thickness in the range of 3-10 nm is used for n-MOSFETs and tensile strained silicon thickness in the range of 1-3 nm is used for p-MOSFETs. The single metal material used in conjunction with the strained-Si—SiGe dual channel layer structure acts as the gate electrode for both n- and p-MOSFET substrates, and the Ge fractions x and y chosen to enable single metal-gate workfunction with suitable threshold voltage for both n-MOSFETs and p-MOSFETs, and to enable enhanced mobilities for electrons and holes. The strained Si and SiGe shifts energy levels allowing workfunctions of n-MOSFET and p-MOSFET to overlap such that a single metal material gate can be chosen with a workfunction in the overlapping region.

The ideal workfunction for metal-gate electrode is determined from the optimal substrate doping condition that provides the best trade-off between short channel effect and impurity mobility degradation for a given off-state leakage requirement. For sub-50 nm MOSFET, the optimal metal-gate workfunction is about 0.2-0.3 eV below conduction band edge for n-MOSFET and about 0.2-0.3 eV above the valence band edge for p-MOSFET. The effect of strain on band structure of Si and SiGe is the key factor that makes it possible for a single metal-gate workfunction to work for both n-MOSFET and p-MOSFET. The tensile strain in the silicon cap layer, where the n-MOSFET channel is, causes the conduction band energy to drop. For example, the conduction band edge of strained Si on relaxed Si_{0.7}Ge_{0.03} drops by 175 meV with respect to that for unstrained silicon. The compressive strain in the SiGe layer, where the p-MOSFET channel is, raises the valence band. For strained Si_{0.4}Ge_{0.6} on relaxed Si_{0.7}Ge_{0.3}, the valence band edge is 380 meV above that of unstrained Si. Because of those band energy level shifts, the range of optimal workfunction for n-MOSFET and p-MOSFET begins to overlap. A single metal material gate electrode thus becomes possible. In this example, the single metal should have workfunction in the range between 4.4 eV to 4.6 eV.

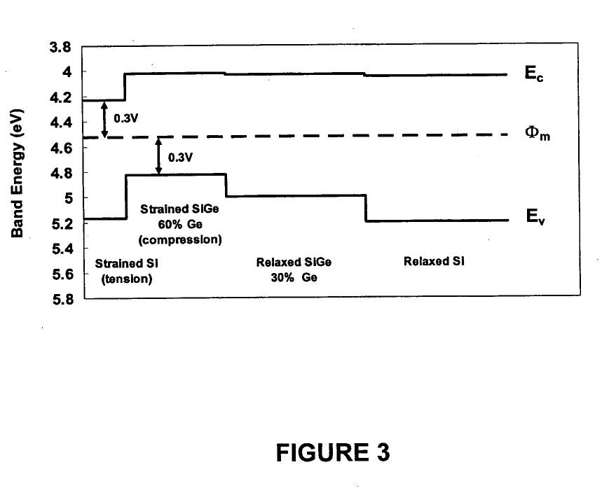

FIG. 3 shows the band structure of the substrate in this invention for the instance of y=0.6 and x=0.3. The difference between the conduction band edge in strained cap Si layer and the valence band edge of the strained SiGe is about 0.6 eV. In the implementation of this invention, a suitable metal electrode material would be chosen. There are a limited number of such metals. The key to the invention is to then adjust the details of the epitaxial heterostructure layer stack to obtain the desired threshold voltages for the n- and p-MOSFETs. It is simple to adjust the epitaxial layer stack properties (e.g., by adjusting the Ge composition), while few if any reliable methods exist to adjust the workfunction of the metal-gate electrode.

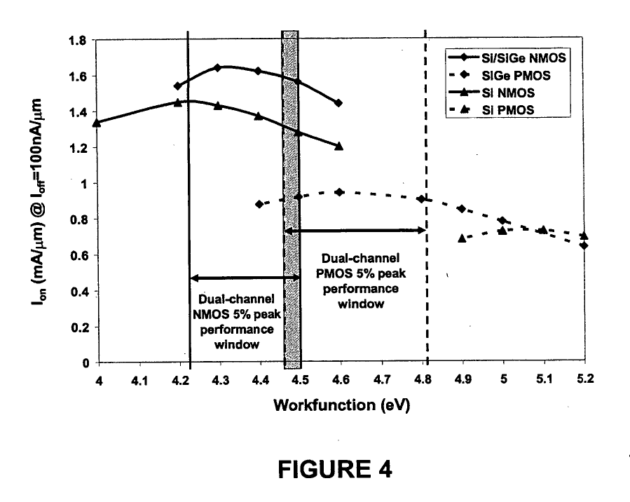

FIG. 4 shows device simulation results for one embodiment of this invention (substrate with y=0.6 and x=0.3). The useable workfunction ranges for n-MOSFET and p-MOSFET overlap, allow a single metal-gate workfunction of 4.5 eV. Meanwhile, no overlap happens for conventional Si substrate.

One of the methods to prepare this structure is through epitaxial growth. First grow a relaxed SiGe layer with gradual increase in Ge content on silicon substrate. When Ge composition reaches the desired value x, a layer of relaxed Si₁₋ₓGeₓ with constant Ge content is grown. Then pseudomorphically grow the compressively strained Si1-yGey with Ge composition y greater than x. Lastly grow a pseudomorphic tensile strained pure silicon cap layer on top. To create a Si cap layer thickness difference between the n-MOSFET region and p-MOSFET region, additional Si etch or oxidation plus oxide etch may be performed in the p-MOSFET region. The Si cap could be completely etched away in the p-MOSFET region followed by re-deposition of thin (less than 2 nm) Si cap layer in either the p-MOSFET region only, or all device regions including n-MOSFET. The p-MOSFET gate stack may be formed by directly depositing high-K gate dielectric following the above-mentioned process or after the complete removal of Si cap layer.

In one embodiment, the present invention's method for forming a strained-Si—SiGe dual channel layer substrate structure and an optimized single metal-gate electrode comprises the steps of: (a) gradually increasing Ge content to a predetermined value x on a silicon substrate and growing a relaxed Si₁₋ₓGeₓ layer; (b) growing a layer of compressively strained Si_{1-y}Ge_{y} on top of the relaxed Si₁₋ₓGeₓ layer, wherein Ge composition y is greater than x; (c) growing a layer of tensile strained silicon on top of the compressively strained Si_{1-y}Ge_{y} layer, and (d) forming an optimized gate stack including a gate dielectric and gate electrode using a single metal material, wherein the single metal material acts as the gate electrode for both n- and p-MOSFETs.

In another embodiment, the present invention's method for forming a strained-Si—SiGe dual channel layer substrate structure and an optimized single metal-gate electrode comprises the steps of: (a) growing a graded buffer layer of Si₁₋ᵣGeᵣ disposed on top of a silicon substrate; (b) growing a relaxed Si₁₋ₓGeₓ layer wherein predetermined value r associated with the buffer layer is chosen such that 0≦r≦x; (c) pseudomorphically growing a layer of compressively strained Si_{1-y}Ge_{y} on top of said relaxed Si₁₋ₓGeₓ layer, wherein Ge composition y>x; (d) pseudomorphically growing a layer of tensile strained silicon on top of the compressively strained Si_{1-y}Ge_{y} layer, wherein varying thickness of the layer of tensile strained silicon provides for n-MOSFET or p-MOSFET substrates, and (e) forming a gate stack consisting of a gate dielectric and a single metal material used as an optimized gate electrode in conjunction with the strained-Si—SiGe dual channel layer structure, wherein the single metal material acts as said gate electrode for both n- and P-MOSFET substrates and the Ge fractions x and y are chosen to enable single metal-gate workfunction with suitable threshold voltage for both n-MOSFETs and p-MOSFETs. The strained Si and SiGe shifts energy levels allowing workfunctions of n-MOSFET and p-MOSFET to overlap such that a single metal material gate can be chosen with a workfunction in the overlapping region.

The CMOS substrate structure proposed in this invention uses only one metal material as gate electrode for both n-channel and p-channel transistors. It significantly simplifies process integration complexity over the existing two different material metal-gate technologies in terms of process complexity. It would have large impact on feasibility of metal-gate technology, process yield, and product cost.

It should be noted that the present invention's teachings may be incorporated in any silicon based integrated circuit process technology, including digital logic, analog products, and memory products.

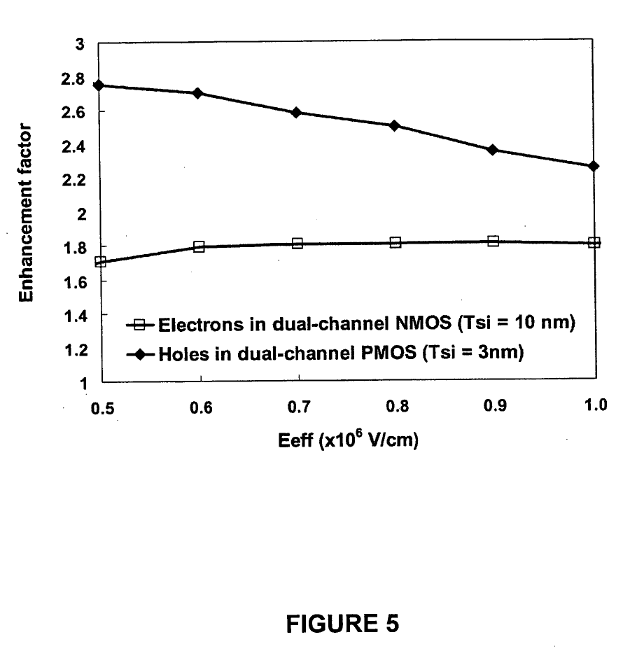

nMOS and pMOS transistors were fabricated on strained-Si—SiGe dual-channel layer substrates with band structure shown FIG. 3. PVD TiN was deposited on 3.3 nm of thermally grown oxide and patterned as the gate electrode. Mobility and drive current enhancements were observed for all dual-channel structures. FIG. 5 shows measured electron and hole mobility enhancement factors (compared to Si control devices) from samples with silicon cap layer thickness of 10 and 3 nm for nMOS and pMOS, respectively. Threshold voltages were also extracted from the current-voltage measurements.

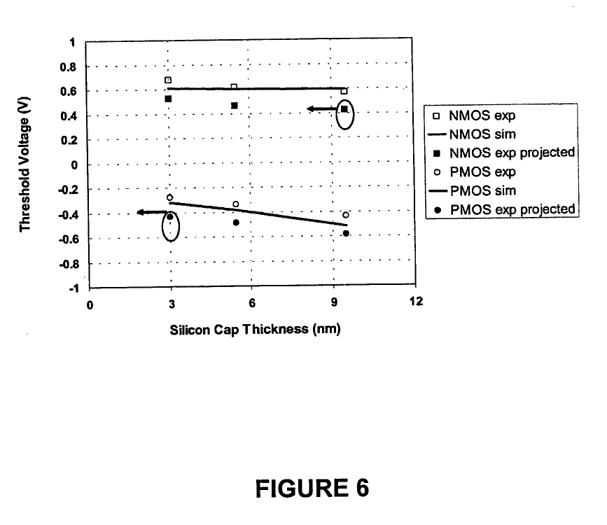

FIG. 6 illustrates a graph of the measured and simulated threshold voltages of long channel nMOS (9.5-nm-thick Si cap layer) and pMOS (3-nm-thick Si cap layer) transistors with TiN gate electrode. FIG. 6 also shows projected threshold voltages with ideal workfunction (4.475 eV) metal-gate electrode. The open symbols in FIG. 6 are measured long-channel (5 μm) threshold voltages of nMOS and pMOS transistors as function of the silicon cap layer thickness. TiN was reported to be a mid-bandgap metal. Device simulation assuming TiN gate electrode workfunction of 4.65 eV matches the threshold voltage reasonably well, as shown by the solid lines in FIG. 6. The substrate doping concentrations were estimated from the implant and annealing conditions. Taking into account the 150-mV gate workfunction value difference between TiN and the ideal metal predicted in the section above for this substrate stack, the projected V_{T} of the transistors with the ideal metal-gate electrode can be computed from the experimentally measured values of transistors with TiN gate (FIG. 6, solid symbols). The projected V_{T} of transistors with metal-gate workfunction of 4.475 eV would be 0.42 V and −0.43 V for nMOS and pMOS, respectively. The symmetry and reasonable values of nMOS and pMOS threshold voltage demonstrates that this strained Si—SiGe heterojunction substrate enables the use of a single workfunction metal-gate.

### CONCLUSION

A system and method has been shown in the above embodiments for the effective implementation of a single metal-gate material CMOS using strained Si-silicon germanium heterojunction layered substrate. While various preferred embodiments have been shown and described, it will be understood that there is no intent to limit the invention by such disclosure, but rather, it is intended to cover all modifications falling within the spirit and scope of the invention, as defined in the appended claims. For example, the present invention should not be limited by specific fractions of Ge or Si, specific thickness of tensile strained silicon, or specific type of metal material used as the gate electrode.

1. A semiconductor structure comprising at least the following layers:
a layer of compressively strained SiGe;
a layer of tensile strained Si disposed on top of said compressively strained SiGe layer, and
an optimized gate stack comprising a gate insulator and a gate electrode, said optimized gate stack formed using a single metal material, wherein strain in said strained Si and strain and/or Ge content in strained SiGe are adjusted to enable use of said single metal material acting as said optimized gate electrode for both n- and p-MOSFETs.

2. A semiconductor structure as per claim 1, wherein said structure further comprises:
a silicon substrate;
a relaxed SiGe layer disposed on top of said substrate;
wherein said compressively strained SiGe is disposed on top of said relaxed SiGe layer.

3. A semiconductor structure as per claim 1, wherein said strained Si and strained SiGe shifts energy levels thereby allowing workfunctions of said n-MOSFET and p-MOSFET to overlap and said single metal material is chosen having a workfunction in the overlapping region.

4. A semiconductor structure as per claim 1, wherein varying thickness of said layer of tensile strained Si provides for n-MOSFETs or p-MOSFETs.

5. A semiconductor structure as per claim 4, wherein N-MOSFET substrates are obtained with a thickness in the range of 3-10 nm.

6. A semiconductor structure as per claim 4, wherein P-MOSFET substrates are obtained with a thickness in the range of 1-3 nm.

7. A semiconductor structure as per claim 1, wherein said single metal material is TiN.

8. A semiconductor structure comprising:
a CMOS substrate structure comprising:
a silicon substrate;
a relaxed Si₁₋ₓGeₓ layer disposed on top of said substrate;
a layer of compressively strained Si_{1-y}Ge_{y} disposed on top of said relaxed Si₁₋ₓGeₓ layer, with Ge composition y being greater than x;
a layer of tensile strained silicon disposed on top of said compressively strained Si_{1-y}Ge_{y} layer, and
an optimized gate stack comprising a gate insulator and a gate electrode, said optimized gate stack formed using a single metal material, said single metal material acting as said gate electrode for both n- and p-MOSFETs.

9. A semiconductor structure as per claim 8, wherein said strained Si and strained SiGe shifts energy levels thereby allowing workfunctions of said n-MOSFET and p-MOSFET to overlap and said single metal material is chosen having a workfunction in the overlapping region.

10. A semiconductor structure as per claim 8, wherein varying thickness of said layer of tensile strained silicon provides for n-MOSFETs or p-MOSFETs.

11. A semiconductor structure as per claim 10, wherein N-MOSFET substrates are obtained with a thickness in the range of 3-10 nm.

12. A semiconductor structure as per claim 10, wherein P-MOSFET substrates are obtained with a thickness in the range of 1-3 nm.

13. A semiconductor structure as per claim 8, wherein said single metal material is TiN.

14. A semiconductor structure as per claim 8, wherein said structure further comprises a graded buffer layer of Si₁₋ᵣGeᵣ disposed between said silicon substrate and said relaxed Si₁₋ₓGeₓ layer, wherein 0≦r≦x.

15. A method for forming a strained-Si—SiGe dual channel layer substrate structure and an optimized single metal-gate electrode comprising the steps of:
forming a layer of compressively strained SiGe;
forming a layer of tensile strained Si disposed on top of said compressively strained SiGe layer, and
forming an optimized gate stack comprising a gate insulator and a gate electrode using a single metal material, wherein strain in said strained Si and strain and/or Ge content in strained SiGe are adjusted to enable use of said single metal material acting as said optimized gate electrode for both n- and p-MOSFETs.

16. A method for forming a strained-Si—SiGe dual channel layer substrate structure and an optimized single metal-gate electrode, as per claim 15, wherein said method further comprises the step of growing a relaxed SiGe layer on a silicon substrate, said layer of compressively strained SiGe grown on top of said relaxed SiGe layer.

17. A method for forming a strained-Si—SiGe dual channel layer substrate structure and an optimized single metal-gate electrode, as per claim 15, wherein said strained Si and strained SiGe causes energy level shifts allowing workfunctions of said n-MOSFET and p-MOSFET to overlap and said single metal material gate is chosen having a workfunction in the overlapping region.

18. A method for forming a strained-Si—SiGe dual channel layer substrate structure and an optimized single metal-gate electrode, as per claim 15, wherein varying thickness of said layer of tensile strained silicon provides for N-MOSFET or P-MOSFET substrates.

19. A method for forming a strained-Si—SiGe dual channel layer substrate structure and an optimized single metal-gate electrode, as per claim 18, wherein N-MOSFET substrates are obtained with a thickness in the range of 3-10 nm.

20. A method for forming a strained-Si—SiGe dual channel layer substrate structure and an optimized single metal-gate electrode, as per claim 18, wherein P-MOSFET substrates are obtained with a thickness in the range of 1-3 nm.

21. A method for forming a strained-Si—SiGe dual channel layer substrate structure and an optimized single metal-gate electrode, as per claim 15, wherein said single metal material is TiN.

22. A method for forming a strained-Si—SiGe dual channel layer substrate structure and an optimized single metal-gate electrode comprising the steps of:
gradually increasing Ge content to a predetermined value x on a silicon substrate and growing a relaxed Si₁₋ₓGeₓ layer;
pseudomorphically growing a layer of compressively strained Si_{1-y}Ge_{y} on top of said relaxed Si₁₋ₓGeₓ layer, with Ge composition y being greater than x;
pseudomorphically growing a layer of tensile strained silicon on top of said compressively strained Si_{1-y}Ge_{y} layer, and
forming an optimized gate stack comprising a gate insulator and a gate electrode, said optimized gate stack formed using a single metal material, said single metal material acting as said gate electrode for both n- and p-MOSFETs.

23. A method for forming a strained-Si—SiGe dual channel layer substrate structure and an optimized single metal-gate electrode, as per claim 22, wherein said strained Si and strained SiGe causes energy level shifts allowing workfunctions of said n-MOSFET and p-MOSFET to overlap and said single metal material gate is chosen having a workfunction in the overlapping region.

24. A method for forming a strained-Si—SiGe dual channel layer substrate structure and an optimized single metal-gate electrode, as per claim 22, wherein varying thickness of said layer of tensile strained silicon provides for N-MOSFET or P-MOSFET substrates.

25. A method for forming a strained-Si—SiGe dual channel layer substrate structure and an optimized single metal-gate electrode, as per claim 24, wherein N-MOSFET substrates are obtained with a thickness in the range of 3-10 nm.

26. A method for forming a strained-Si—SiGe dual channel layer substrate structure and an optimized single metal-gate electrode, as per claim 24, wherein P-MOSFET substrates are obtained with a thickness in the range of 1-3 nm.

27. A method for forming a strained-Si—SiGe dual channel layer substrate structure and an optimized single metal-gate electrode, as per claim 22, wherein said single metal material is TiN.

28. A method for forming a strained-Si—SiGe dual channel layer substrate structure and an optimized single metal-gate electrode, as per claim 22, wherein said method further comprises the step of growing a graded buffer layer of Si₁₋ᵣGeᵣ disposed on top of a silicon substrate, wherein said grown relaxed Si₁₋ₓGeₓ layer is disposed on top of said graded buffer layer of Si₁₋ᵣGeᵣ and predetermined value r associated with the buffer layer is chosen such that 0≦r≦x.
